(19) United States
(12) Patent Application Publication
(10) Pub. No.: US 2016/0035968 A1
(43) Pub. Date: Feb. 4, 2016

(54) PRODUCING METHOD OF SUSPENSION BOARD WITH CIRCUIT

(71) Applicant: NITTO DENKO CORPORATION, Osaka (JP)

(72) Inventors: Takatoshi SAKAKURA, Osaka (JP); Hitoki KANAGAWA, Osaka (JP)

(73) Assignee: NITTO DENKO CORPORATION, Osaka (JP)

(21) Appl. No.: 14/794,085

(22) Filed: Jul. 8, 2015

(30) Foreign Application Priority Data
Jul. 29, 2014 (JP) 2014-153870

(51) Int. Cl. H01L 41/257; H01L 41/25

(52) U.S. Cl. CPC H01L 41/257; H01L 41/25

(57) ABSTRACT

A method for producing a suspension board with circuit includes a first step of preparing a suspension board including a metal supporting layer, a base insulating layer disposed at one surface in a thickness direction of the metal supporting layer, and a conductive pattern disposed at one surface in the thickness direction of the base insulating layer and having a terminal portion; a second step of connecting a piezoelectric element to the terminal portion by solder and heating the solder at a temperature of not less than a depolarization temperature allowing polarization of the piezoelectric element to start disappearing; and a third step of applying a voltage to the piezoelectric element so as to repolarize the piezoelectric element connected to the terminal portion.

### CROSS-REFERENCE TO RELATED APPLICATION

The present application claims priority from Japanese Patent Application No. 2014-153870 filed on Jul. 29, 2014, the contents of which are hereby incorporated by reference into this application.

### BACKGROUND OF THE INVENTION

1. Field of the Invention

The present invention relates to a method for producing a suspension board with circuit, to be specific, to a method for producing a suspension board with circuit mounted with a piezoelectric element.

2. Description of Related Art

A suspension board with circuit mounted with a head slider and a piezoelectric element capable of stretching and shrinking in order to displace the head slider has been conventionally known. Such a piezoelectric element is connected to a terminal included in the suspension board with circuit.

The piezoelectric element is generally formed of piezoelectric ceramics such as lead zirconate titanate or the like. When the temperature of the piezoelectric element excessively increases, there may be a case where polarization of the piezoelectric element disappears and a stretching amount thereof is reduced. Thus, connection of a piezoelectric element to a terminal without excessive increase in temperature of the piezoelectric element has been variously considered.

For example, a suspension board in which a piezoelectric element is connected to an element connecting terminal by a solder member for element having a melting point of 180° C. or less has been proposed (ref: for example, Japanese Unexamined Patent Publication No. 2014-106993).

### SUMMARY OF THE INVENTION

In the suspension board described in Japanese Unexamined Patent Publication No. 2014-106993, however, there is a need for using a solder member having a melting point of 180° C. or less, to be more specific, a specific solder member such as an Sn (tin)-Bi (bismuth) solder member. Thus, there is a limit in improving a degree of freedom in material design of the solder member.

It is an object of the present invention to provide a method for producing a suspension board with circuit that is capable of improving a degree of freedom in material design of solder and ensuring the stretching properties of a piezoelectric element.

[1] A method for producing a suspension board with circuit of the present invention includes a first step of preparing a suspension board including a metal supporting layer, a base insulating layer disposed at one surface in a thickness direction of the metal supporting layer, and a conductive pattern disposed at one surface in the thickness direction of the base insulating layer and having a terminal portion; a second step of connecting a piezoelectric element to the terminal portion by solder and heating the solder at a temperature of not less than a depolarization temperature allowing polarization of the piezoelectric element to start disappearing; and a third step of applying a voltage to the piezoelectric element so as to repolarize the piezoelectric element connected to the terminal portion.

According to the producing method, in the second step, the solder is melted by being heated at the temperature of not less than the depolarization temperature, so that the piezoelectric element is connected to the terminal portion by the solder.

At this time, there may be a case where the temperature of the piezoelectric element increases to not less than the depolarization temperature and the polarization of the piezoelectric element disappears. However, in the third step, a voltage is applied to the piezoelectric element so as to repolarize the piezoelectric element, so that the polarization of the piezoelectric element is restored and the stretching properties thereof are retrieved.

That is, in the producing method of the present invention, in the second step, in addition to solder having a melting point of not more than the depolarization temperature, solder having a melting point of not less than the depolarization temperature can be used, so that the stretching properties of the piezoelectric element can be ensured, while the degree of freedom in material design of the solder can be improved.

[2] In the method for producing a suspension board with circuit of the present invention described in the above-described [1], the depolarization temperature is not less than a half of the Curie temperature of the piezoelectric element.

According to the producing method, in the second step, the solder is heated at a temperature of not less than a half of the Curie temperature of the piezoelectric element, so that the solder can be surely melted and the connection reliability of the piezoelectric element with the terminal portion can be improved.

[3] In the method for producing a suspension board with circuit of the present invention described in the above-described [1] or [2], in the first step, the plurality of suspension boards are prepared and the plurality of suspension boards are configured as an assembly in which the terminal portions thereof are electrically connected to each other; in the second step, the plurality of piezoelectric elements are prepared and each of the plurality of piezoelectric elements is connected to each of the terminal portions of the plurality of suspension boards by solder; and in the third step, by applying a voltage to the assembly, a voltage is collectively applied to the plurality of piezoelectric elements via each of the terminal portions of the plurality of suspension boards.

According to the producing method, in the third step, by applying a voltage to the assembly, a voltage is collectively applied to the plurality of piezoelectric elements, so that the polarization of the plurality of piezoelectric elements is collectively restored.

Thus, compared to a case where a voltage is separately applied to each of the plurality of piezoelectric elements, the number of producing steps can be reduced. As a result, the productivity of the suspension board with circuit can be improved.

### BRIEF DESCRIPTION OF THE DRAWINGS

FIG. 1 shows an explanatory view for illustrating a method for producing a suspension board with circuit of the present invention and illustrates a step of preparing a suspension board assembly.

FIG. 2, subsequent to FIG. 1, shows an explanatory view for illustrating a method for producing a suspension board with circuit and illustrates a step of disposing solder in first terminals and second terminals.

FIG. 3, subsequent to FIG. 2, shows an explanatory view for illustrating a method for producing a suspension board with circuit and illustrates a step of mounting piezoelectric elements and sliders.

FIG. 4 shows an enlarged view of a suspension board shown in FIG. 3.

FIG. 5A shows an A-A sectional view of a suspension board shown in FIG. 1.

FIG. 5B shows a B-B sectional view of a suspension board shown in FIG. 2.

FIG. 5C shows a C-C sectional view of a suspension board shown in FIG. 3.

### DETAILED DESCRIPTION OF THE INVENTION

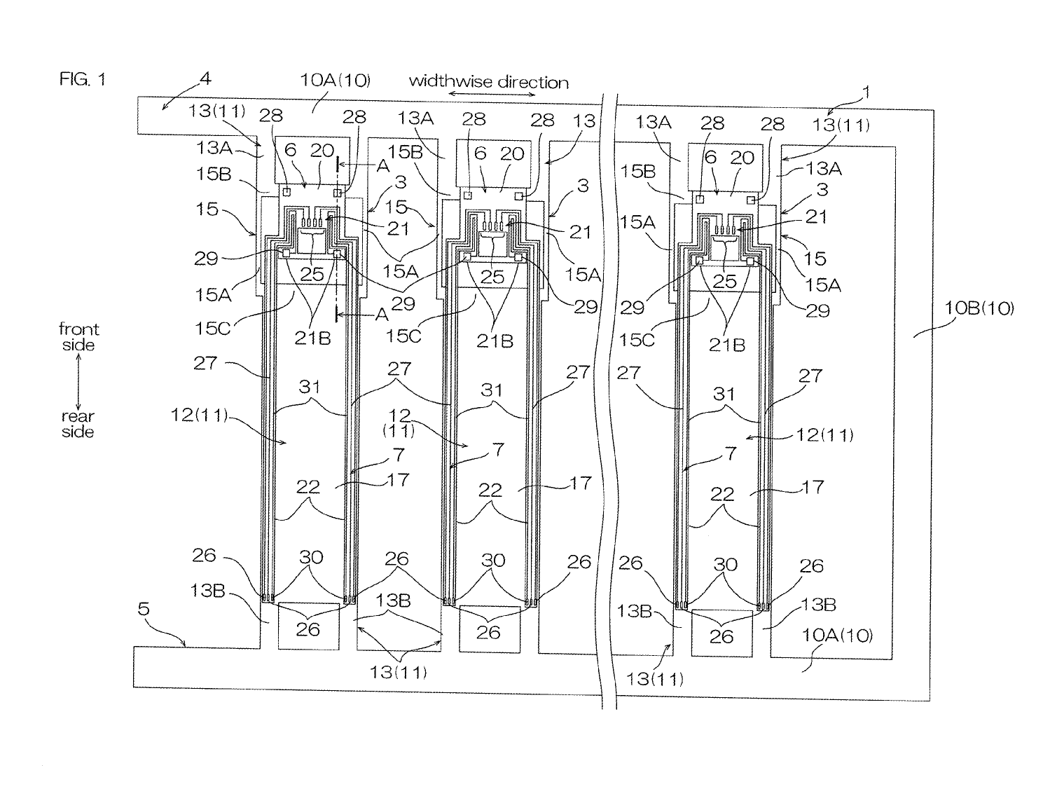

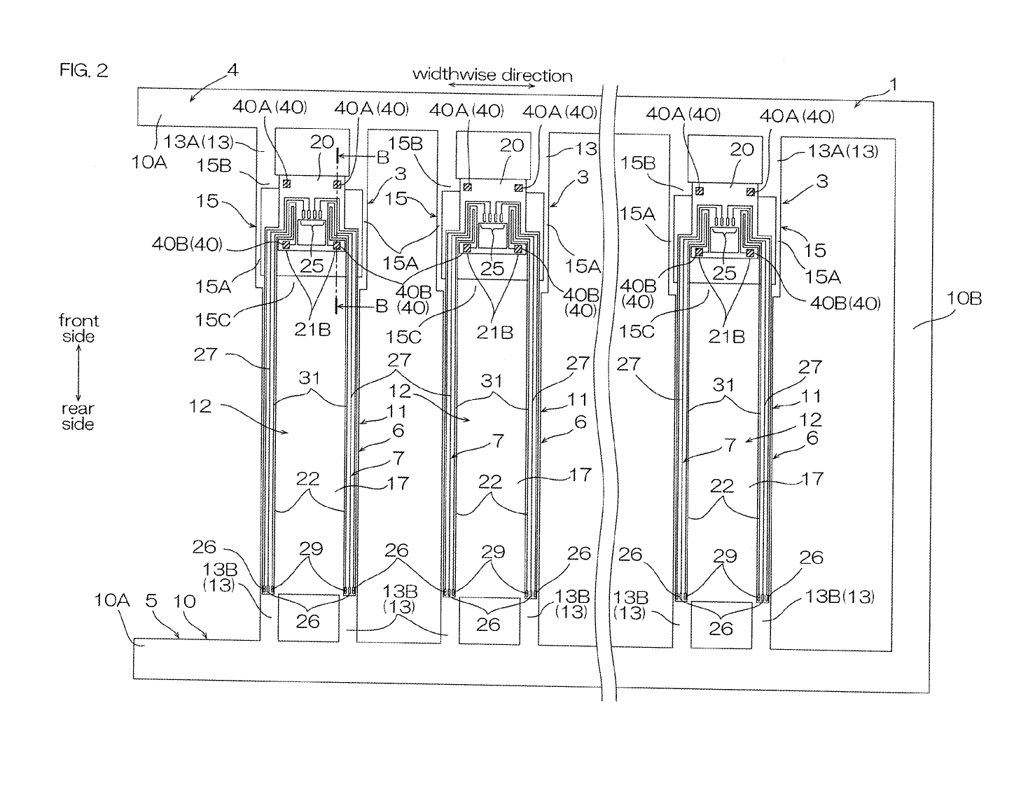

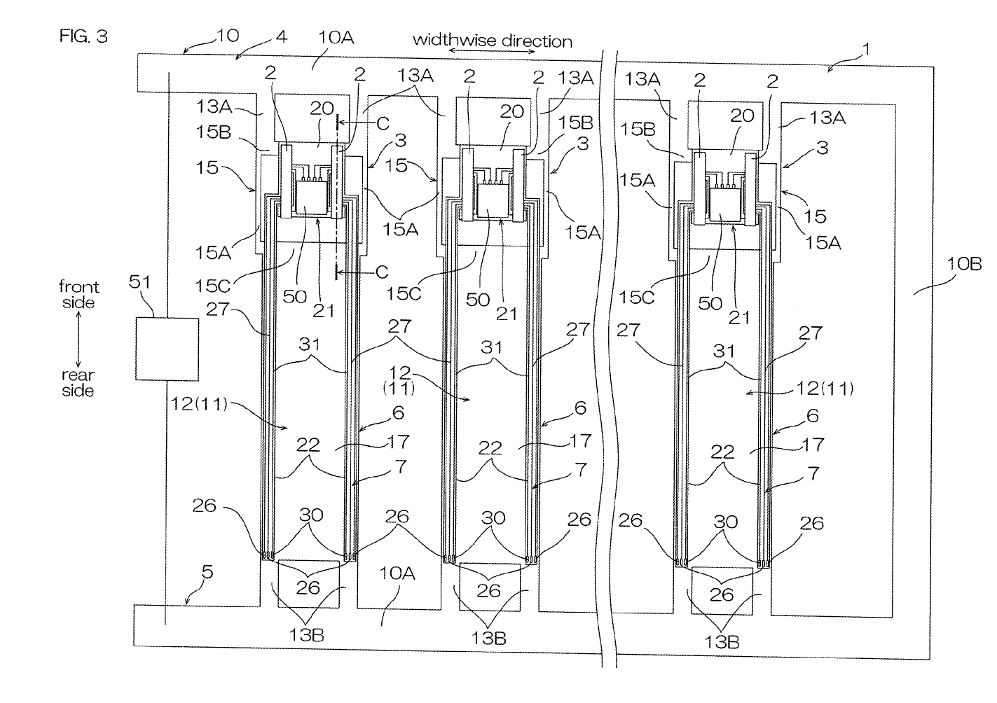

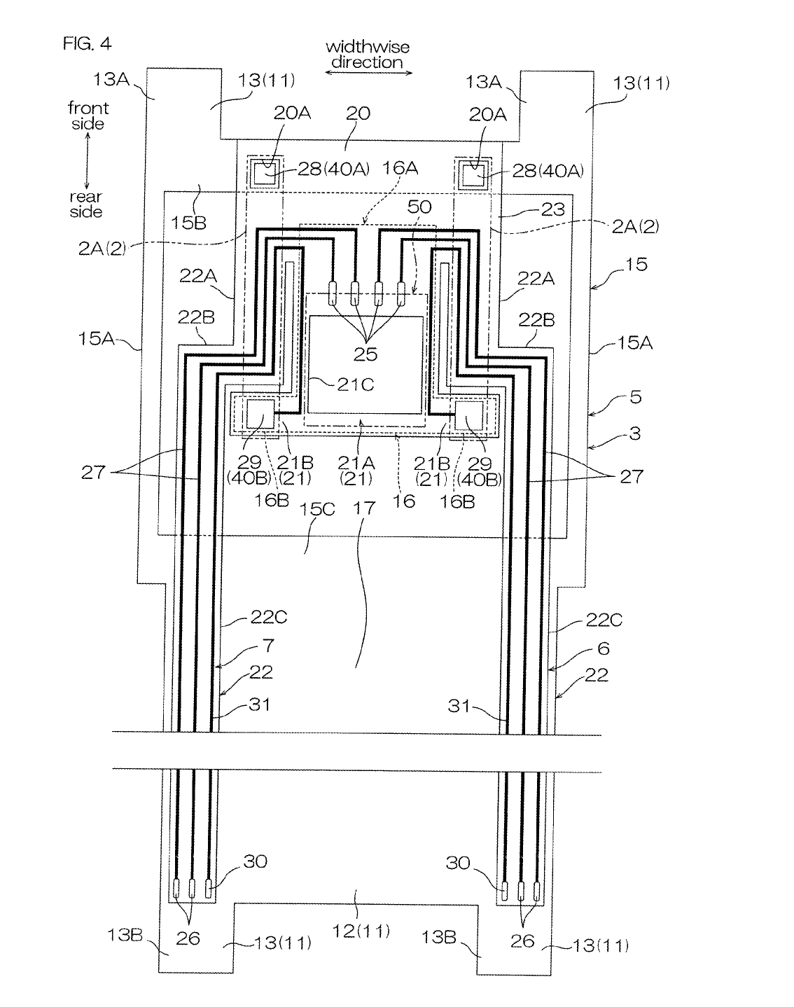

A method for producing a suspension board with circuit of the present invention includes a first step (ref: FIG. 1) of preparing a suspension board assembly 1 including a plurality of suspension boards 3; a second step (ref: FIGS. 2 and 3) of connecting piezoelectric elements 2 to each of the suspension boards 3; a third step (ref: FIG. 3) of collectively applying a voltage to the plurality of piezoelectric elements 2; and a fourth step (ref: FIG. 4) of cutting out each of the suspension boards 3 from the suspension board assembly 1.

According to the method for producing a suspension board with circuit, as shown in FIG. 1, first, in the first step, the suspension board assembly 1 as one example of an assembly is prepared.

The suspension board assembly 1 includes the plurality of suspension boards 3 and a frame 4.

Each of the plurality of suspension boards 3 is formed into a flat belt shape extending in an up-down direction of the paper surface. The plurality of suspension boards 3 are disposed at spaced intervals to each other in a right-left direction of the paper surface.

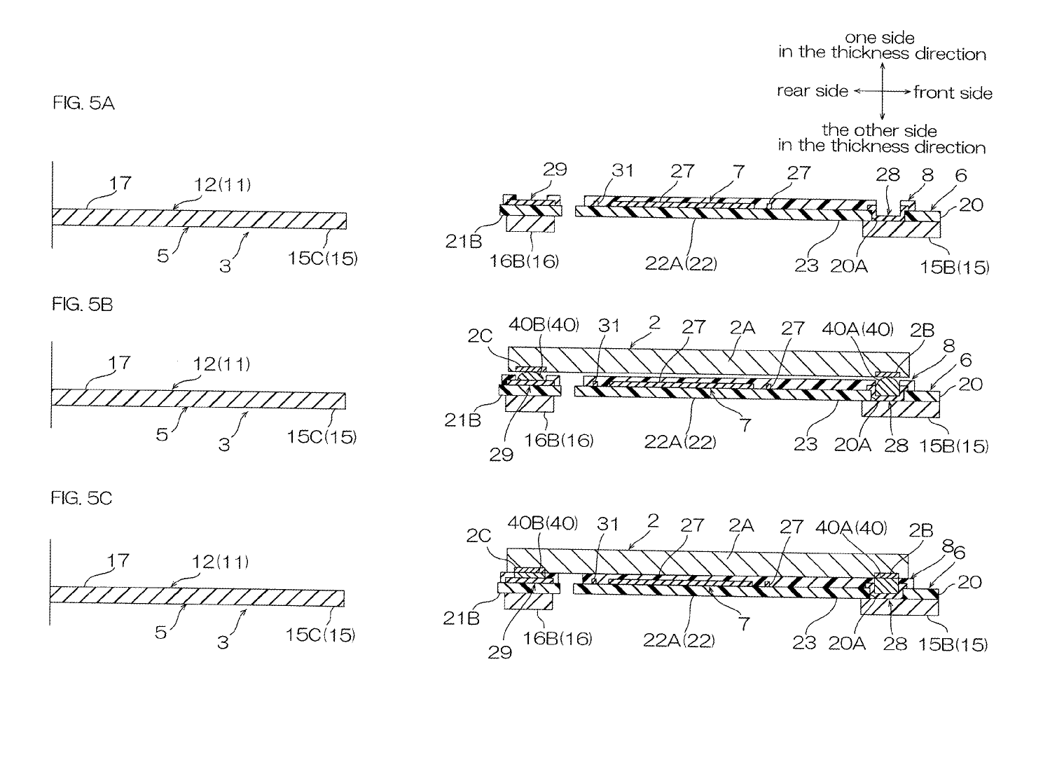

In the description below, when referring to the direction of the suspension board assembly 1 and the suspension board 3, the up-down direction of the paper surface in FIG. 1 is referred to as a front-rear direction and the right-left direction of the paper surface in FIG. 1 is referred to as a widthwise direction. The up-down direction of the paper surface in FIGS. 5A to 5C is referred to as a thickness direction. The upper side of the paper surface in FIGS. 5A to 5C is one side in the thickness direction and the lower side of the paper surface in FIGS. 5A to 5C is the other side in the thickness direction.

The frame 4 is, when viewed from the thickness direction, formed into a generally U-shape having an opening toward one side in the widthwise direction and is disposed so as to surround the plurality of suspension boards 3. The frame 4 supports the plurality of suspension boards 3 by connecting each of both end portions in the front-rear direction of each of the suspension boards 3 thereto.

As shown in FIG. 5C, the suspension board assembly 1 has a laminating structure. To be specific, the suspension board assembly 1 is formed by sequentially laminating, as one example of a metal supporting layer, a supporting board 5, a base insulating layer 6, a conductive pattern 7, and a cover insulating layer 8 from the other side toward one side in the thickness direction. In FIGS. 1 to 4, the cover insulating layer 8 is omitted for convenience.

As shown in FIG. 1, the supporting board 5 includes a frame portion 10 corresponding to the frame 4 and a plurality of board portions 11 corresponding to the plurality of suspension boards 3.

The frame portion 10 is, when viewed from the thickness direction, formed into a generally U-shape having an opening toward one side in the widthwise direction. The frame portion 10 includes a pair of board supporting portions 10A and a bridge portion 10B.

The pair of board supporting portions 10A is both end portions in the front-rear direction of the frame portion 10. The board supporting portions 10A are disposed at spaced intervals to each other in the front-rear direction. Each of the pair of board supporting portions 10A is, when viewed from the thickness direction, formed into a generally rectangular plate shape extending in the widthwise direction.

The bridge portion 10B is disposed between the other end portions in the widthwise direction of the board supporting portions 10A. The bridge portion 10B is, when viewed from the thickness direction, formed into a generally rectangular plate shape extending in the front-rear direction.

The plurality of board portions 11 are disposed between the pair of board supporting portions 10A in the front-rear direction and are disposed in parallel at spaced intervals to each other in the widthwise direction.

As shown in FIGS. 1 and 4, each of the board portions 11 includes a board main body 12 and connecting portions 13.

As shown in FIG. 4, the board main body 12 is formed into a flat belt shape extending in the front-rear direction and includes a gimbal portion 15, a reinforcing portion 16, and a wire supporting portion 17.

The gimbal portion 15 is the front end portion of the board main body 12 and is, when viewed from the thickness direction, formed into a generally rectangular frame shape. To be more specific, the gimbal portion 15 includes a plurality (two pieces) of outrigger portions 15A, a front-side continuous portion 15B, and a rear-side continuous portion 15C.

The pair of outrigger portions 15A is both end portions in the right-left direction of the gimbal portion 15. The outrigger portions 15A are disposed at spaced intervals to each other in the widthwise direction. Each of the outrigger portions 15A is, when viewed from the thickness direction, formed into a generally rectangular shape extending in the front-rear direction.

The front-side continuous portion 15B is the front end portion of the gimbal portion 15 and is disposed between the front end portions of the outrigger portions 15A. The front-side continuous portion 15B is, when viewed from the thickness direction, formed into a generally rectangular shape extending in the widthwise direction.

The rear-side continuous portion 15C is the rear end portion of the gimbal portion 15 and is disposed between the rear end portions of the outrigger portions 15A. The rear-side continuous portion 15C is, when viewed from the thickness direction, formed into a generally rectangular shape extending in the widthwise direction.

As shown in FIG. 4, the reinforcing portion 16 is, at the inside of the gimbal portion 15, disposed at spaced intervals to the gimbal portion 15. The reinforcing portion 16 is, when viewed from the thickness direction, formed into a generally T-shape and includes a rectangular portion 16A and a pair of protruding portions 16B.

The rectangular portion 16A is, when viewed from the thickness direction, formed into a generally rectangular shape extending in the front-rear direction.

The pair of protruding portions 16B is disposed at both sides in the widthwise direction with respect to the rear end portion of the rectangular portion 16A and protrudes from each of both end portions in the widthwise direction of the rectangular portion 16A toward both sides in the widthwise direction. Each of the protruding portions 16B is, when viewed from the thickness direction, formed into a generally rectangular shape.

The wire supporting portion 17 is formed into a generally flat belt shape extending from the rear end portion of the gimbal portion 15 to be continuous rearwardly.

As shown in FIG. 1, the connecting portions 13 are portions that connect the board main body 12 to the frame portion 10 and include a pair of front-side connecting portions 13A and a pair of rear-side connecting portions 13B.

The pair of front-side connecting portions 13A is disposed between the front-side continuous portion 15B of the gimbal portion 15 and the board supporting portion 10A at the front side. The front-side connecting portions 13A are disposed at spaced intervals to each other in the widthwise direction and extend from both end portions in the widthwise direction of the front-side continuous portion 15B forwardly to be connected to the rear end edge of the board supporting portion 10A at the front side.

The pair of rear-side connecting portions 13B is disposed between the wire supporting portion 17 and the board supporting portion 10A at the rear side. The rear-side connecting portions 13B are disposed at spaced intervals to each other in the widthwise direction and extend from both end portions in the widthwise direction of the rear end portion of the wire supporting portion 17 rearwardly to be connected to the front end edge of the board supporting portion 10A at the rear side.

The supporting board 5 is formed of, for example, a metal material such as stainless steel, 42-alloy, aluminum, copper-beryllium, and phosphor bronze. Preferably, the supporting board 5 is formed of stainless steel. The supporting board 5 has a thickness of, for example, 10 μm or more, and, for example, 50 μm or less, or preferably 25 μm or less.

As shown in FIGS. 4 and 5C, the base insulating layer 6 is laminated (disposed) on the upper surface (one surface in the thickness direction) of the board main body 12. The base insulating layer 6 includes a first terminal forming portion 20, a slider mounting portion 21, a plurality (two pieces) of wire forming portions 22, and a connecting portion 23.

The first terminal forming portion 20 is disposed on the front-side continuous portion 15B. As shown in FIG. 4, the first terminal forming portion 20 is, when viewed from the thickness direction, formed into a generally rectangular shape extending in the widthwise direction. A plurality (two pieces) of through holes 20A are formed in the first terminal forming portion 20.

Each of the plurality of through holes 20A is disposed at both end portions in the widthwise direction of the first terminal forming portion 20. Each of the plurality of through holes 20A is, when viewed from the thickness direction, formed into a rectangular shape and passes through the first terminal forming portion 20 in the thickness direction (ref: FIG. 5A).

The slider mounting portion 21 is disposed on the reinforcing portion 16. The slider mounting portion 21 includes a main body portion 21A and a pair of second terminal forming portions 21B.

The main body portion 21A is disposed on the rectangular portion 16A of the reinforcing portion 16. The main body portion 21A is formed into almost the same shape as the outer shape of the rectangular portion 16A of the reinforcing portion 16. The outer circumference edge of the main body portion 21A is disposed at slightly outer side with respect to that of the rectangular portion 16A of the reinforcing portion 16. An opening 21C is formed in the main body portion 21A.

The opening 21C is disposed at the center in the widthwise direction of the main body portion 21A. The opening 21C is, when viewed from the thickness direction, formed into a generally rectangular shape and passes through the main body portion 21A in the thickness direction.

The pair of second terminal forming portions 21B is disposed on the pair of protruding portions 16B of the reinforcing portion 16. The second terminal forming portion 21B is formed into almost the same shape as the outer shape of the protruding portion 16B of the reinforcing portion 16. The outer circumference edge of the second terminal forming portion 21B is, when viewed from the thickness direction, disposed at slightly outer side with respect to that of the protruding portion 16B of the reinforcing portion 16.

Each of the plurality of wire forming portions 22 is disposed at the outer side in the widthwise direction of the slider mounting portion 21. Each of the plurality of wire forming portions 22 includes a first linear portion 22A, a swelling portion 22B, and a second linear portion 22C.

The first linear portion 22A is the front end portion of the wire forming portion 22 and is disposed at both sides in the widthwise direction of the main body portion 21A of the slider mounting portion 21 at spaced intervals thereto. Also, the first linear portion 22A is disposed at the inner side in the widthwise direction of the outrigger portion 15A at spaced intervals thereto. The first linear portion 22A is, when viewed from the thickness direction, formed into a generally linear shape extending in the front-rear direction. The front end portion thereof is continuous to that of the main body portion 21A of the slider mounting portion 21. The rear end portion thereof is disposed at the front side of the second terminal forming portion 21B.

The swelling portion 22B extends rearwardly so as to go around the outer side in the widthwise direction of the second terminal forming portion 21B. To be more specific, the swelling portion 22B extends from the rear end portion of the first linear portion 22A to be continuous toward the outer side in the widthwise direction and bends rearwardly to extend rearwardly at the outer side in the widthwise direction of the second terminal forming portion 21B. The swelling portion 22B is disposed at the outer side in the widthwise direction of the second terminal forming portion 21B at spaced intervals thereto. The swelling portion 22B is disposed at the inner side in the widthwise direction of the outrigger portion 15A at spaced intervals thereto.

The second linear portion 22C extends from the rear end portion of the swelling portion 22B to be continuous toward the rear side. The second linear portion 22C is disposed on the wire supporting portion 17.

The connecting portion 23 connects the rear end portion of the first terminal forming portion 20 to each of the front end portions of the slider mounting portion 21 and the wire forming portion 22. The connecting portion 23 is, when viewed from the thickness direction, formed into a generally rectangular shape extending in the widthwise direction.

The base insulating layer 6 is formed of, for example, a synthetic resin such as polyimide, polyamideimide, acryl, polyether, nitrile, polyether sulfone, polyethylene terephthalate (PET), polyethylene naphthalate, and polyvinyl chloride. Preferably, in view of thermal dimensional stability or the like, the base insulating layer 6 is formed of polyimide. The base insulating layer 6 has a thickness of, for example, 1 μm or more, or preferably 3 μm or more, and, for example, 35 μm or less, or preferably 20 μm or less.

The conductive pattern 7 is disposed on the upper surface (one surface in the thickness direction) of the base insulating layer 6. The conductive pattern 7 includes a plurality (four pieces) of magnetic head-connecting terminals 25; a plurality (four pieces) of first external connecting terminals 26; a plurality (four pieces) of first wires 27; as one example of a terminal portion, a plurality (two pieces) of first terminals 28; a plurality (two pieces) of second terminals 29; a plurality (two pieces) of second external connecting terminals 30; and a plurality (two pieces) of second wires 31.

The plurality of magnetic head-connecting terminals 25 are, at the front-side portion of the slider mounting portion 21, disposed in parallel at spaced intervals to each other in the widthwise direction. Each of the plurality of magnetic head-connecting terminals 25 is, when viewed from the thickness direction, formed into a generally rectangular shape extending in the front-rear direction.

Each of the plurality of first external connecting terminals 26 is to be connected to an external control board (not shown) or the like. The shape, arrangement, and connecting method thereof can be arbitrarily selected in accordance with the configuration of the external control board (not shown). To be specific, in the embodiment, the plurality of first external connecting terminals 26 are, at the rear end portion of the wire forming portion 22, disposed in parallel at spaced intervals to each other in the widthwise direction. Each of the plurality of first external connecting terminals 26 is, when viewed from the thickness direction, formed into a generally rectangular shape extending in the front-rear direction.

The plurality of first wires 27 are formed at spaced intervals to each other so that each of them is continuous from the front end portion of the corresponding magnetic head-connecting terminal 25 to be continuous to the first external connecting terminal 26 by going through the upper surfaces of the main body portion 21A of the slider mounting portion 21 and the wire forming portion 22.

Each of the plurality of first terminals 28 is disposed at both end portions in the widthwise direction of the first terminal forming portion 20 so as to seal each of the plurality of through holes 20A (ref: FIG. 5A). Each of the plurality of first terminals 28 is, when viewed from the thickness direction, formed into a generally rectangular shape.

As shown in FIG. 5A, each of the plurality of first terminals 28 is in contact with the front-side continuous portion 15B in the gimbal portion 15 via each of the plurality of through holes 20A. In this manner, each of the plurality of first terminals 28 is electrically connected (grounded) to the front-side continuous portion 15B of the gimbal portion 15. That is, the first terminals 28 in the plurality of suspension boards 3 are electrically connected to each other via the supporting board 5.

Each of the plurality of second terminals 29 is disposed on the corresponding second terminal forming portion 21B. As shown in FIG. 4, each of the plurality of second terminals 29 is, when viewed from the thickness direction, formed into a generally rectangular shape.

Each of the plurality of second external connecting terminals 30 is to be connected to an external control board (not shown) or the like. The shape, arrangement, and connecting method thereof can be arbitrarily selected in accordance with the configuration of the external control board (not shown). To be specific, in the embodiment, the plurality of second external connecting terminals 30 are, at the rear end portion of the wire forming portion 22, disposed at the inner side in the widthwise direction with respect to the entire first external connecting terminals 26. Each of the plurality of second external connecting terminals 30 is, when viewed from the thickness direction, formed into a generally rectangular shape.

Each of the plurality of second wires 31 is formed to be continuous from the inner-side end portion in the widthwise direction of the corresponding second terminal 29, go forwardly on the main body portion 21A of the slider mounting portion 21 to be then folded back rearwardly, and thereafter, be continuous to the second external connecting terminal 30 by going rearwardly on the upper surface of the wire forming portion 22.

The conductive pattern 7 is, for example, formed of a conductive material such as copper, nickel, gold, and solder or an alloy thereof. Preferably, the conductive pattern 7 is formed of copper. The conductive pattern 7 has a thickness of, for example, 3 μm or more, or preferably 5 μm or more, and, for example, 30 μm or less, or preferably 20 μm or less.

The cover insulating layer 8 is formed on the upper surface (one surface in the thickness direction) of the base insulating layer 6 so as to expose the magnetic head-connecting terminals 25, the first external connecting terminals 26, the central portions of the first terminals 28, the central portions of the second terminals 29, and the second external connecting terminals 30 and to cover the circumferential end portions of the first terminals 28, the circumferential end portions of the second terminals 29, the first wires 27, and the second wires 31.

The cover insulating layer 8 is formed of the same synthetic resin as that of the base insulating layer 6. Preferably, the cover insulating layer 8 is formed of polyimide. The cover insulating layer 8 has a thickness of, for example, 2 μm or more, or preferably 4 μm or more, and, for example, 20 μm or less, or preferably 15 μm or less.

Next, the piezoelectric elements 2 are connected to each of the suspension boards 3 (the second step).

To connect the piezoelectric elements 2 to each of the suspension boards 3, first, as shown in FIGS. 1 and 2, solders 40 are disposed on the upper surfaces (one surfaces in the thickness direction) of the first terminals 28 and the second terminals 29.

Examples of an alloy that forms the solder 40 include tin (Sn)-lead (Pb), tin (Sn)-bismuth (Bi), zinc (Zn)-aluminum (Al), tin (Sn)-copper (Cu), tin (Sn)-antimony (Sb), tin (Sn)-silver (Ag), tin (Sn)-zinc (Zn), tin (Sn)-silver (Ag)-lead (Pb), tin (Sn)-lead (Pb)-bismuth (Bi), tin (Sn)-antimony (Sb)-lead (Pb), tin (Sn)-bismuth (Bi)-copper (Cu), tin (Sn)-bismuth (Bi)-indium (In), tin (Sn)-bismuth (Bi)-silver (Ag), tin (Sn)-copper (Cu)-nickel (Ni), tin (Sn)-zinc (Zn)-bismuth (Bi), tin (Sn)-silver (Ag)-copper (Cu), tin (Sn)-silver (Ag)-aluminum (Al), tin (Sn)-silver (Ag)-antimony (Sb)-lead (Pb), tin (Sn)-zinc (Zn)-copper (Cu)-nickel (Ni), tin (Sn)-copper (Cu)-bismuth (Bi)-nickel (Ni), tin (Sn)-copper (Cu)-bismuth (Bi)-indium (In), tin (Sn)-silver (Ag)-copper (Cu)-antimony (Sb), tin (Sn)-silver (Ag)-copper (Cu)-nickel (Ni), tin (Sn)-silver (Ag)-nickel (Ni)-cobalt (Co), tin (Sn)-silver (Ag)-bismuth (Bi)-copper (Cu), tin (Sn)-copper (Cu)-nickel (Ni)-cobalt (Co), tin (Sn)-copper (Cu)-nickel (Ni)-germanium (Ge), tin (Sn)-silver (Ag)-copper (Cu)-indium (In), tin (Sn)-silver (Ag)-copper (Cu)-nickel (Ni)-germanium (Ge), tin (Sn)-silver (Ag)-copper (Cu)-nickel (Ni)-indium (In), tin (Sn)-silver (Ag)-copper (Cu)-bismuth (Bi)-indium (In), tin (Sn)-silver (Ag)-copper (Cu)-bismuth (Bi)-nickel (Ni), and tin (Sn)-copper (Cu)-nickel (Ni)-germanium (Ge)-cobalt (Co).

Among these alloys that form the solder 40, preferably, Sn—Ag—Cu is used.

The solder 40 has a melting point of, for example, 70° C. or more, or preferably 180° C. or more, and, for example, 350° C. or less, or preferably 250° C. or less.

As a method for disposing the solder 40 on the upper surfaces of the first terminal 28 and the second terminal 29, for example, printing with a known printer, application with a dispenser, or the like is used.

As shown in FIG. 5B, of the solders 40, the solder 40 (hereinafter, referred to as a first solder 40A) that is disposed on each of the upper surfaces of the first terminals 28 has a size in the thickness direction of for example, 0.1 μm or more, or preferably 1 μm or more, and, for example, 500 μm or less, or preferably 300 μm or less. One end portion in the thickness direction of each of the first solders 40A preferably protrudes with respect to one surface in the thickness direction of the cover insulating layer 8.

Of the solders 40, the solder 40 (hereinafter, referred to as a second solder 40B) that is disposed on each of the upper surfaces of the second terminals 29 has a size in the thickness direction of, for example, 0.1 μm or more, or preferably 1 μm or more, and, for example, 500 μm or less, or preferably 300 μm or less. One end portion in the thickness direction of each of the second solders 40B preferably protrudes with respect to one surface in the thickness direction of the cover insulating layer 8.

Subsequently, the plurality of piezoelectric elements 2 corresponding to the plurality of suspension boards 3 are prepared.

The piezoelectric element 2 is an actuator that is capable of stretching and shrinking in the front-rear direction. The piezoelectric element 2 stretches and shrinks by allowing electricity to supply thereto and its voltage to be controlled.

As shown in FIG. 5B, the piezoelectric element 2 includes an element main body 2A, a first element terminal 2B, and a second element terminal 2C.

As shown in FIG. 4, the element main body 2A is, when viewed from the thickness direction, formed into a rectangular shape extending in the front-rear direction. The element main body 2A is, for example, formed of a known piezoelectric material, to be more specific, piezoelectric ceramics or the like.

Examples of the piezoelectric ceramics include BaTiO₃ (barium titanate, Curie point: about 135° C.), PbTiO₃ (lead titanate, Curie point: about 490° C.), Pb(Zr,Ti)O₃ (lead zirconate titanate (PZT), Curie point: about 350° C.), SiO₂ (crystal, Curie point: about 573° C.), LiNbO₃ (lithium niobate, Curie point: about 1210° C.), and PbNb₂O₆ (lead metaniobate, Curie point: about 570° C.). Preferably, PZT is used.

The piezoelectric ceramics has a Curie point (temperature) of, for example, 100° C. or more, or preferably 130° C. or more, and, for example, 400° C. or less, or preferably 370° C. or less. The Curie point (temperature) is the critical temperature at which polarization of a piezoelectric material completely disappears.

As shown in FIG. SB, the first element terminal 2B is disposed in the front end portion on the lower surface (the other surface in the thickness direction) of the element main body 2A and is electrically connected to the element main body 2A.

The second element terminal 2C is disposed in the rear end portion on the lower surface of the element main body 2A and is disposed at spaced intervals to the first element terminal 2B at the rear side thereof. The second element terminal 2C is electrically connected to the element main body 2A.

As shown in FIG. 3, two pieces of piezoelectric elements 2 are disposed in each of the plurality of suspension boards 3.

As shown in FIG. 4, the two pieces of piezoelectric elements 2 corresponding to each of the suspension boards 3 are disposed at spaced intervals to each other in the widthwise direction. As shown in FIG. 5B, each of the piezoelectric elements 2 is disposed at the upper side (one side in the thickness direction) with respect to the cover insulating layer 8 so that the first element terminal 2B is in contact with the corresponding first solder 40A and the second element terminal 2C is in contact with the second solder 40B.

In the embodiment, the piezoelectric elements 2 are disposed and a slider 50 is disposed on the upper surface (one surface in the thickness direction) of the slider mounting portion 21 in the base insulating layer 6.

The slider 50 is, when viewed from the thickness direction, formed into a rectangular shape and has a plurality of magnetic heads that is not shown at the front end portion thereof. The plurality of magnetic heads that are not shown are provided corresponding to the plurality of magnetic head-connecting terminals 25.

To be more specific, the slider 50 is attached to the reinforcing portion 16 that is exposed from the opening 21C (ref: FIG. 1) in the slider mounting portion 21 via an adhesive. Each of the magnetic heads that is not shown is disposed at the rear side of the corresponding magnetic head-connecting terminal 25 at slightly spaced intervals thereto.

Thereafter, a solder ball that is not shown is disposed between the magnetic head that is not shown and the corresponding magnetic head-connecting terminal 25.

Subsequently, the suspension board assembly 1 in which the plurality of piezoelectric elements 2 and the sliders 50 are disposed is reflowed.

To reflow the suspension board assembly 1, the suspension board assembly 1 is heated at a temperature of not less than a depolarization starting temperature of the element main body 2A of the piezoelectric element 2 in a reflow furnace.

The depolarization starting temperature is a temperature at which polarization of the element main body 2A of the piezoelectric element 2 starts disappearing, strictly speaking, a temperature at which 1% of polarization of the element main body 2A disappears. The depolarization starting temperature is generally not less than a half of the Curie temperature of the piezoelectric material, or for example, about two thirds of the Curie temperature of the piezoelectric material.

The heating temperature is not less than the depolarization starting temperature and not less than the melting point of the solder 40. The heating temperature is, for example, 180° C. or more, preferably 200° C. or more, or more preferably 220° C. or more, and, for example, 300° C. or less, or preferably 250° C. or less. The heating time is, for example, 10 seconds or more, or preferably 15 seconds or more, and, for example, 180 seconds or less, or preferably 60 seconds or less.

In this manner, as shown in FIG. 5C, the first solder 40A is melted spreadly on the entire upper surface (one surface in the thickness direction) of the first terminal 28, so that the first element terminal 2B is connected to the first terminal 28. The second solder 40B is melted spreadly on the entire upper surface of the second terminal 29, so that the second element terminal 2C is connected to the second terminal 29.

That is, each of the plurality of piezoelectric elements 2 is connected to each of the first terminals 28 and the second terminals 29 in the plurality of suspension boards 3 by the solders 40.

Also, the solder ball that is not shown is melted, so that the magnetic head that is not shown is connected to the corresponding magnetic head-connecting terminal 25.

In this manner, the second step is completed by mounting the piezoelectric elements 2 and the slider 50 in each of the plurality of suspension boards 3.

In the second step, however, the suspension board assembly 1 in which the plurality of piezoelectric elements 2 are disposed is heated at a temperature of not less than a depolarization starting temperature of the element main body 2A, so that a part of or the entire polarization of the element main body 2A of the piezoelectric element 2 disappears and the stretching properties of the piezoelectric element 2 are reduced.

Next, as shown in FIG. 3, a voltage is collectively applied to the plurality of piezoelectric elements 2 so as to repolarize the piezoelectric elements 2 (the third step).

To collectively apply a voltage to the plurality of piezoelectric elements 2, first, a known voltage applying device 51 is electrically connected to the frame portion 10 in the supporting board 5.

Then, a voltage is applied from the voltage applying device 51 to the frame portion 10.

The applied voltage is, for example, 1 V or more, or preferably 30 V or more, and, for example, 1000 V or less, or preferably 200 V or less.

The applied time of the voltage is, for example, 1 second or more, or preferably 5 seconds or more, and, for example, 60 seconds or less, or preferably 30 seconds or less.

In this manner, as shown in FIGS. 3 and 5C, the voltage from the voltage applying device 51 is sequentially transmitted to the frame portion 10, the pair of front-side connecting portions 13A, and the front-side continuous portion 15B to be applied to the first element terminals 2B of the piezoelectric elements 2 via the first terminals 28 and the first solders 40A.

That is, the voltage from the voltage applying device 51 is transmitted to the supporting board 5 (the frame portion 10, the pair of front-side connecting portions 13A, and the front-side continuous portion 15B) to be collectively applied to the plurality of piezoelectric elements 2 via the first terminals 28 in each of the suspension boards 3. Then, in the element main bodies 2A of the piezoelectric elements 2, the polarization in which at least a part thereof disappears in the second step is restored (repolarized), so that the stretching properties thereof are retrieved.

Next, each of the suspension boards 3 is cut out from the suspension board assembly 1 (the fourth step).

To cut out each of the suspension boards 3 from the suspension board assembly 1, as shown in FIGS. 3 and 4, the connecting portions 13 (the front-side connecting portions 13A and the rear-side connecting portions 13B) of each of the suspension boards 3 are cut midway in the front-rear direction thereof.

In this manner, as shown in FIG. 4, the suspension boards 3 (one example of a suspension board with circuit) mounted with the piezoelectric elements 2 are cut out from the suspension board assembly 1.

In the method for producing a suspension board with circuit, as shown in FIG. 5C, in the second step, the solder 40 is melted by being heated at a temperature of not less than a depolarization temperature, so that the piezoelectric element 2 is connected to the first terminal 28 by the solder 40.

Thus, in the second step, there may be a case where the temperature of the element main body 2A of the piezoelectric element 2 increases to not less than the depolarization temperature and the polarization of the element main body 2A disappears. In this respect, as shown in FIG. 3, in the third step, a voltage is applied to the piezoelectric element 2 so as to repolarize the element main body 2A, so that the polarization of the element main body 2A is restored and the stretching properties thereof are retrieved.

In the second step, the solder 40 is heated at a temperature of not less than a half of the Curie temperature of the element main body 2A of the piezoelectric element 2, so that the solder 40 can be surely melted and the connection reliability of the first element terminal 2B with the first terminal 28 can be improved.

In the third step, by applying a voltage to the frame portion 10 in the suspension board assembly 1, a voltage is collectively applied to the plurality of piezoelectric elements 2. Thus, even when at least a part of the polarization of the element main bodies 2A of the plurality of piezoelectric elements 2 disappears in the second step, the polarization of the element main bodies 2A of the plurality of piezoelectric elements 2 is collectively restored in the third step.

As a result, compared to a case where a voltage is separately applied to each of the plurality of piezoelectric elements 2, the number of producing steps can be reduced. Consequently, the productivity of the suspension board 3 mounted with the piezoelectric elements 2 can be improved.

In the above-described embodiment, in the first step, the suspension board assembly 1 including the plurality of suspension boards 3 is prepared. However, the preparation method is not limited to this and the suspension board 3 can be prepared one by one. In such a case, in the second step, the piezoelectric elements 2 are mounted on the individual suspension boards 3 and in the third step, a voltage is applied to the individual suspension boards 3 mounted with the piezoelectric elements 2.

In the above-described embodiment, in the second step, along with the piezoelectric elements 2, the slider 50 is mounted on the suspension board 3. However, the timing of mounting the slider 50 on the suspension board 3 is not particularly limited as long as it is after the first step. Alternatively, for example, the slider 50 may be also mounted on the suspension board 3 after the third step or may be also mounted on the suspension board 3 that is cut out from the suspension board assembly 1 after the fourth step.

As in the above-described embodiment, however, in view of reduction of reflow step, preferably, both of the piezoelectric elements 2 and the slider 50 are mounted on the suspension board 3 in the second step.

The same function and effect as that of the above-described embodiment can be also achieved in the modified examples.

Each of the above-described embodiment and the modified examples can be appropriately used in combination.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A method for producing a suspension board with circuit comprising:
a first step of preparing a suspension board including a metal supporting layer, a base insulating layer disposed al one surface in a thickness direction of the metal supporting layer, and a conductive pattern disposed at one surface in a thickness direction of the base insulating layer and having a terminal portion;
a second step of connecting a piezoelectric element to the terminal portion by solder and heating the solder at a temperature of not less than a depolarization temperature allowing polarization of the piezoelectric element to start disappearing; and
a third step of applying a voltage to the piezoelectric element so as to repolarize the piezoelectric element connected to the terminal portion.

2. The method for producing a suspension board with circuit according to claim 1, wherein
the depolarization temperature is not less than a half of the Curie temperature of the piezoelectric element.

3. The method for producing a suspension board with circuit according to claim 1, wherein
in the first step, a plurality of suspension boards are prepared and the plurality of suspension boards are configured as an assembly in which a terminal portions thereof are electrically connected to each other;
in the second step, a plurality of piezoelectric elements are prepared and each of the plurality of piezoelectric elements is connected to each of the terminal portions of the plurality of suspension boards by solder; and
in the third step, by applying a voltage to the assembly, a voltage is collectively applied to the plurality of piezoelectric elements via each of the terminal portions of the plurality of suspension boards.
